(19) United States
(12) Patent Application Publication
(10) Pub. No.: US 2025/0351392 A1
(43) Pub. Date: Nov. 13, 2025

(54) SEMICONDUCTOR DEVICES AND ELECTRONIC DEVICES INCLUDING THE SAME

(71) Applicant: Samsung Electronics Co., Ltd., Suwon-si (KR)

(72) Inventors: Kunsik Sung, Suwon-si (KR); Myoungsoo Kim, Suwon-si (KR)

(21) Appl. No.: 19/204,710

(22) Filed: May 12, 2025

(30) Foreign Application Priority Data
May 8, 2024 (KR) 10-2024-0104184

(51) Int. Cl. H10D 8/60; H10D 8/01

(52) U.S. Cl. CPC H10D 8/60; H10D 8/051

(57) ABSTRACT

A semiconductor device that includes a substrate that includes a first doping region having a first conductivity type, an edge doping region having a second conductivity type that is different from the first conductivity type, and a second doping region having the first conductivity type, wherein the edge doping region is at an edge region of the first doping region; a first device isolator between the edge doping region and the second doping region at a first surface of the substrate; a gate structure that is on the edge doping region and the first device isolator and includes a gate insulation layer and a gate electrode; a first electrode that includes a first electrode portion on the first doping region and the edge doping region, and a second electrode portion electrically connected to the gate electrode; and a second electrode that is electrically connected to the second doping region.

### CROSS-REFERENCE TO RELATED APPLICATIONS

This application claims priority to and the benefit of Korean Patent Application No. 10-2024-0104184 filed in the Korean Intellectual Property Office on Aug. 5, 2024, the entire contents of which are incorporated herein by reference.

### BACKGROUND OF THE INVENTION

The present disclosure relates to semiconductor devices and electronic devices including the same.

A Schottky barrier diode is a semiconductor device using a Schottky junction between a semiconductor material and metal. The Schottky barrier diode may have an operation property of majority carriers, which enables fast switching. The Schottky barrier diode may be driven by tunneling using the Schottky junction between the semiconductor material and the metal and may have a lower turn-on voltage than a p-n junction diode.

The Schottky barrier diode may be included in various electronic devices. Typically, Schottky barrier diodes may have an external structure that is separately manufactured from an electronic device and is mounted on the electronic device. Additional cost and time are required when using the Schottky barrier diode of the external structure.

### SUMMARY OF THE INVENTION

The present disclosure may provide a semiconductor device capable of having enhanced performance and productivity and an electronic device including the same.

A semiconductor device according to some embodiments may include a substrate that includes a first doping region having a first conductivity type, an edge doping region having a second conductivity type that is different from the first conductivity type, and a second doping region having the first conductivity type, wherein the edge doping region is at an edge region of the first doping region; a first device isolator between the edge doping region and the second doping region at a first surface of the substrate; a gate structure that is on the edge doping region and the first device isolator and includes a gate insulation layer and a gate electrode; a first electrode that includes a first electrode portion on the first doping region and the edge doping region, and a second electrode portion electrically connected to the gate electrode; and a second electrode that is electrically connected to the second doping region.

A semiconductor device according to some embodiments may include a substrate that includes a n-type doping region, a field relief guard ring having a p-type conductivity, and a high concentration n-type doping region that is spaced apart from the field relief guard ring, wherein the field relief guard ring is at an edge region of the n-type doping region, and wherein the high concentration n-type doping region has a higher doping concentration than the n-type doping region at a first surface of the substrate; a gate structure that includes a gate insulation layer and a gate electrode, wherein the gate structure overlaps the field relief guard ring in a direction that is perpendicular to the first surface of the substrate; an anode electrode that includes a first electrode portion on the n-type doping region and the field relief guard ring to comprise a Schottky junction with the n-type doping region, and a second electrode portion that is spaced apart from the first electrode portion and is electrically connected to the gate electrode; and a cathode electrode that is electrically connected to the high concentration n-type doping region.

An electronic device according to some embodiments may include a first semiconductor device; and a second semiconductor device that has a different structure from the first semiconductor device, wherein the first semiconductor device includes: a substrate that includes a first doping region having a first conductivity type, an edge doping region having a second conductivity type that is different from the first conductivity type, and a second doping region having the first conductivity type, wherein the edge doping region is at an edge region of the first doping region; a first device isolator between the edge doping region and the second doping region at a first surface of the substrate; a gate structure that is on the edge doping region and the first device isolator and includes a gate insulation layer and a gate electrode; a first electrode that includes a first electrode portion on the first doping region and the edge doping region, and a second electrode portion electrically connected to the gate electrode; and a second electrode that is electrically connected to the second doping region.

According to some embodiments, by an edge doping region of a field relief guard ring, a threshold voltage in a reverse bias may increase. The edge doping region may be disposed in a substrate, and the edge doping region may be easily formed and the edge doping region may be disposed in an entire portion where an edge (region) of a first electrode portion of a first electrode is disposed. A gate structure may be disposed on the edge doping region and increase a current density in a forward bias. Accordingly, the current density in the forward bias may increase while maintaining the threshold voltage in the reverse bias high, and performance of a semiconductor device may be enhanced.

According to some embodiments, the semiconductor device having enhanced performance may be formed by an easy (more convenient) process and productivity may be enhanced.

### BRIEF DESCRIPTION OF THE DRAWINGS

FIG. 1 is a cross-sectional view of a semiconductor device according to some embodiments.

FIG. 2 is a plan view that schematically illustrates a first doping region, an edge doping region, a device isolator, a first electrode, a second electrode, and a third electrode included in the semiconductor device illustrated in FIG. 1.

FIG. 3 is a plan view that schematically illustrates the first electrode and a portion of a wiring layer (electrically) connected to the first electrode, which are included in the semiconductor device illustrated in FIG. 1.

FIG. 4 schematically illustrates a depletion region and holes of a semiconductor device according to some embodiments in a reverse bias.

FIG. 5 schematically illustrates a depletion region and electrodes of a semiconductor device according to some embodiments in a forward bias.

FIGS. 6 to 9 are cross-sectional views that illustrate a manufacturing method of a semiconductor device.

FIG. 10 is a perspective view that illustrates an example of an electronic device including a semiconductor device according to some embodiments.

FIG. 11 is a cross-sectional view that conceptually illustrates a plurality of semiconductor devices included in the electronic device illustrated in FIG. 10.

### DETAILED DESCRIPTION

Embodiments of the present disclosure will be described more fully hereinafter with reference to the accompanying drawings for those skilled in the art to which the present disclosure pertains to easily practice the present disclosure. The present disclosure may be implemented in various forms and is not limited to the embodiment provided herein.

A portion unrelated to the description may be omitted in order to clearly describe the present disclosure, and the same or similar components may be denoted by the same reference numeral throughout the present specification unless clearly described otherwise.

Further, since a size and/or a thickness of a portion, a region, a member, a unit, a layer, a film, a substrate, or so on illustrated in the accompanying drawings may be arbitrarily illustrated for better understanding and convenience of explanation, the present disclosure is not limited to the illustrated size and/or thickness. In the drawings, a thickness of a portion, a region, a member, a unit, a layer, a film, a substrate, or so on may be enlarged or exaggerated for convenience of explanation and/or simple illustration. As used herein, the term “and/or” includes any and all combinations of one or more of the associated listed items.

It will be understood that when a component such as a portion, a region, a member, a unit, a layer, a film, a substrate, or so on is referred to as being “on” another component, it may be directly on another component or an intervening component may also be present. In contrast, when a component is referred to as being “directly on” another component, there is no intervening component present. Further, when a component is referred to as being “on” or “above” a reference component, a component may be positioned on or below the reference component, and does not necessarily be “on” or “above” the reference component toward an opposite direction of gravity.

In addition, throughout the specification, unless explicitly described to the contrary, the word “comprise”, “include”, or “contain”, and variations such as “comprises”, “comprising”, “includes”, “including”, “contains” or “containing” will be understood to imply the inclusion of other components rather than the exclusion of any other components.

Further, throughout the specification, a phrase “on a plane”, “in a plane”, “on a plan view”, or “in a plan view” may indicate a case where a portion is viewed from above or a top portion, and a phrase “on a cross-section” or “in a cross-sectional view” may indicate a case where a cross-section taken along a vertical direction is viewed from a side.

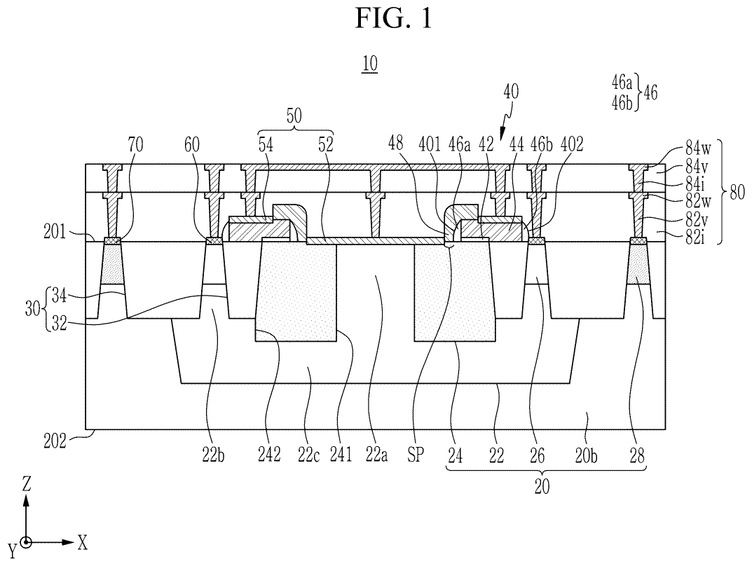

Hereinafter, with reference to FIGS. 1 to 5, a semiconductor device 10 according to some embodiments will be described in detail.

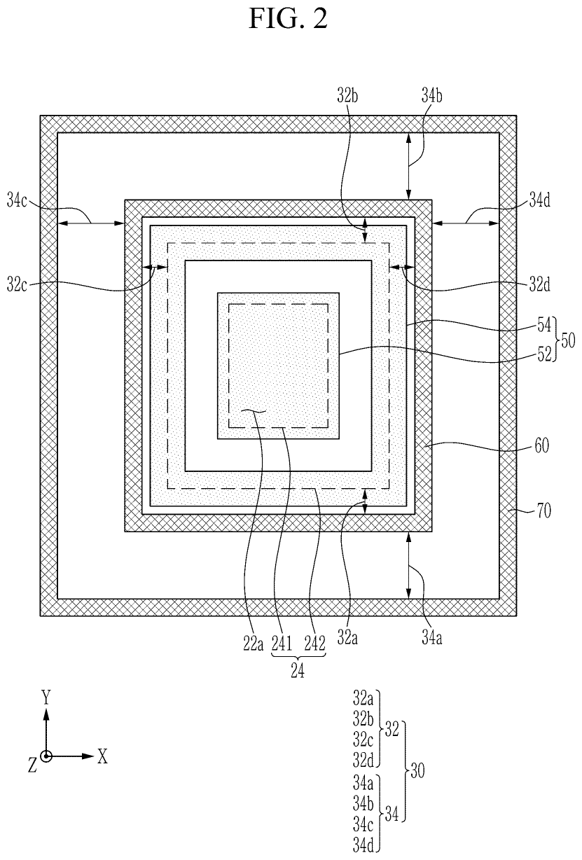

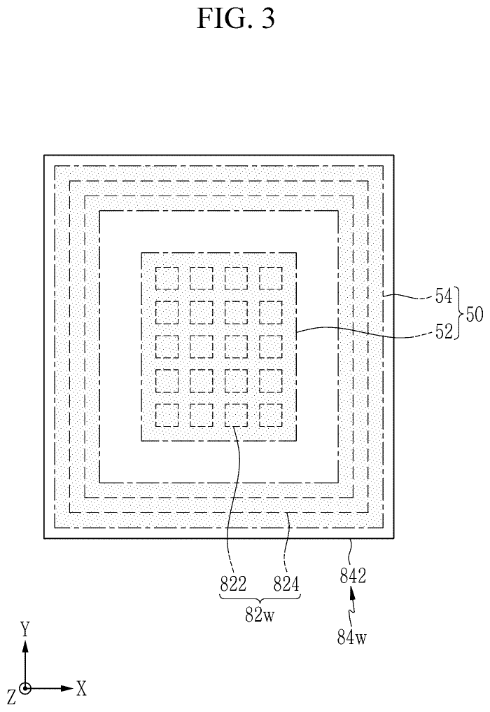

FIG. 1 is a cross-sectional view of a semiconductor device 10 according to some embodiments. FIG. 2 is a plan view that schematically illustrates a first doping region 22, an edge doping region 24, a device isolator 30, a first electrode 50, a second electrode 60, and a third electrode 70 included in the semiconductor device 10 illustrated in FIG. 1. FIG. 3 is a plan view that schematically illustrates the first electrode 50 and a portion of a wiring layer 82w or 84w (electrically) connected to the first electrode 50, which are included in the semiconductor device 10 illustrated in FIG. 1.

Referring to FIGS. 1 to 3, a semiconductor device 10 according to some embodiments may include a substrate 20, a device isolator 30, a gate structure 40, a first electrode 50, and a second electrode 60. The semiconductor device 10 may further include a third electrode 70 and a wiring portion 80.

The substrate 20 may include or be formed of a semiconductor material. For example, the substrate 20 may be a silicon substrate (e.g., a single-crystalline silicon substrate or a polycrystalline silicon substrate) that includes or be formed of silicone. However, the embodiments are not limited thereto. In some embodiments, the substrate 20 may include or be formed of silicon-germanium, germanium, silicon on insulator (SOI), germanium on insulator (GOI), or so on.

The substrate 20 may include a first surface 201 and a second surface 202 that are opposite to each other. The first surface 201 of the substrate 20 may be an active surface where various circuit elements including the semiconductor device 10 are disposed, and the second surface 202 of the substrate 20 may be an opposite surface that is opposite to the active surface (in a Z-axis direction). The substrate 20 may have a shape of a flat plate that has a predetermined area in an XY-plane in the drawings and has a predetermined thickness in a Z-axis direction in the drawings.

In some embodiments, the substrate 20 may include a first doping region 22, an edge doping region 24, and a second doping region 26, and may further include a bulk region 20b and a third doping region 28. The device isolator 30 may be provided to divide or separate at least two of the first doping region 22, the edge doping region 24, the second doping region 26, the third doping region 28, and the bulk region 20b. For example, the device isolator 30 may be between at least two of the first doping region 22, the edge doping region 24, the second doping region 26, the third doping region 28, and the bulk region 20b.

Each of the first doping region 22, the edge doping region 24, the second doping region 26, and the third doping region 28 may be a doping region formed by doping the substrate 20 with a dopant. The bulk region 20b may be a region of the substrate 20 where the first doping region 22, the edge doping region 24, the second doping region 26, and the third doping region 28 are not disposed.

The device isolator 30 may have a shallow trench isolation (STI) structure configured to divide, separate, and/or define an active region (at the first surface 201 of) the substrate 20. The device isolator 30 may extend in (e.g., pass through or penetrate) a portion of the substrate 20 (e.g., at a side of the first surface 201 of the substrate 20). For example, a first surface of the device isolator 30 disposed at the side of the first surface 201 of the substrate 20 may be disposed on the same plane as (e.g., coplanar with) the first surface 201 of the substrate 20, and a second surface of the device isolator 30 disposed at a side of the second surface 202 of the substrate 20 may be spaced apart from the second surface 202 of the substrate 20 (in the Z-axis direction). However, the embodiments are not limited thereto. In some embodiments, the first surface of the device isolator 30 disposed at the side of the first surface 201 of the substrate 20 may be disposed on a different plane from the first surface 201 of the substrate 20.

The device isolator 30 may include or be formed of silicon oxide, silicon nitride, silicon oxynitride, and/or a low dielectric constant material. The low dielectric constant material may be a material having a dielectric constant lower than a dielectric constant of silicon oxide. However, the embodiments are not limited thereto, and the device isolator 30 may include any of various materials.

In a cross-sectional view, a width of the device isolator 30 (in the X-axis direction and/or the Y-axis direction) may gradually decrease from the first surface of the device isolator 30 to the second surface of the device isolator 30, and a side surface of the device isolator 30 may include or be formed of an inclined surface that is inclined to (the first surface 201 and/or the second surface 202 of) the substrate 20. However, the embodiments are not limited thereto, and a cross-sectional shape of the device isolator 30 may be variously modified.

In some embodiments, the device isolator 30 may include a first device isolator 32 and a second device isolator 34. The first device isolator 32 may be disposed to have a first region (e.g., an inner region) inside the first device isolator 32. The second device isolator 34 may be disposed to have a second region (e.g., an intermediate region) inside the second device isolator 34. The second region may be disposed outside the first device isolator 32. For example, the second region may be between the first device isolator 32 and the second device isolator 34 (in the X-axis direction and/or the Y-axis direction). A third region (e.g., an outer region) may be disposed outside the second device isolator 34.

For example, the first device isolator 32 may include at least a first isolation portion 32a and a second isolation portion 32b. The first isolation portion 32a and the second isolation portion 32b may be opposite to each other (in the Y-axis direction) and extend in a first direction (the X-axis direction in the drawings). The first device isolator 32 may further include a third isolation portion 32c and a fourth isolation portion 32d. The third isolation portion 32c and the fourth isolation portion 32d may be opposite to each other (in the X-axis direction) and extend in a second direction (the Y-axis direction in the drawings) that intersects (e.g., is perpendicular to) the first direction.

Thereby, (in a plan view) the first device isolator 32 may have a frame shape that extends around (e.g., surrounds) the first region. In a plan view, the first region inside the first device isolator 32 may have a planar shape of a rectangular shape and a closed shape. However, the embodiments are not limited thereto. A planar shape of the first device isolator 32 and/or a planar shape or an arrangement of the first region defined by the first device isolator 32 may be variously modified.

For example, the second device isolator 34 may include a first isolation portion 34a and a second isolation portion 34b. The first isolation portion 34a and the second isolation portion 34b of the second device isolator 34 may be spaced apart (in Y-axis direction) from the first isolation portion 32a and the second isolation portion 32b of the first device isolator 32, respectively, by a predetermined interval, and may be disposed outside the first isolation portion 32a and the second isolation portion 32b of the first device isolator 32. The first isolation portion 34a and the second isolation portion 34b of the second device isolator 34 may be opposite to each other (in the Y-axis direction) and extend in the first direction (the X-axis direction in the drawings). The second device isolator 34 may further include a third isolation portion 34c and a fourth isolation portion 34d. The third isolation portion 34c and the fourth isolation portion 34d may be opposite to each other (in the X-axis direction) and extend in the second direction (the Y-axis direction in the drawings) that intersects (e.g., is perpendicular to) the first direction. The third isolation portion 34c and the fourth isolation portion 34d of the second device isolator 34 may be spaced apart (in the X-axis direction) from the third isolation portion 32c and the fourth isolation portion 32d of the first device isolator 32, respectively, by a predetermined interval, and may be disposed outside the third isolation portion 32c and the fourth isolation portion 32d of the first device isolator 32.

Thereby, in a plan view, the second device isolator 34 may have a frame shape that extends around (e.g., surrounds) the first region, the first device isolator 32, and the second region. In a plan view, the second region between the first device isolator 32 and the second device isolator 34 may have a frame shape that extends along an edge of the first device isolator 32 and/or an edge of the first region, and the second region between the first device isolator 32 and the second device isolator 34 may have a closed shape. In a plan view, the second region between the first device isolator 32 and the second device isolator 34 may have an outer edge having a rectangular shape. However, the embodiments are not limited thereto. A shape of the second device isolator 34 and/or a shape or an arrangement of the second region between the first device isolator 32 and the second device isolator 34 may be variously modified.

In the first region inside the first device isolator 32, the first doping region 22 and the edge doping region 24 may be disposed. For example, the first doping region 22 and the edge doping region 24 may overlap the first region inside the first device isolator 32 and/or the first device isolator 32 in a third direction (e.g., the Z-axis direction). In the second region between the first device isolator 32 and the second device isolator 34, the second doping region 26 may be disposed. In some embodiments, the first doping region 22 may overlap the second region between the first device isolator 32 and the second device isolator 34 and the second device isolator 34 in the third direction (e.g., the Z-axis direction). In the third region outside the second device isolator 34, the third doping region 28 may be disposed. That is, the first device isolator 32 may divide or separate the edge doping region 24 from the second doping region 26 at the side of the first surface 201 of the substrate 20. For example, the first device isolator 32 may be between the edge doping region 24 and the second doping region 26 (in the X-axis direction and/or the Y-axis direction). The edge doping region 24 may be disposed at an edge portion of the first doping region 22 (e.g., a first portion 22a of the first doping region 22) at the side of the first surface 201 of the substrate 20. The edge portion (also referred to as the edge region) of an element (e.g., the first doping region 22) may refer to an area adjacent to (a side of) element (e.g., the first doping region 22). The second device isolator 34 may divide or separate the second doping region 26 and/or the first doping region 22 (e.g., a second portion 22b of the first doping region 22) from the third doping region 28 and/or the bulk region 20b at the side of the first surface 201 of the substrate 20. For example, the second device isolator 34 may be between the second portion 22b of the first doping region 22 and the third doping region 28 in the X-axis direction and/or Y-axis direction. The second device isolator 34 may be between the second portion 22b of the first doping region 22 and the bulk region 20b in the X-axis direction and/or Y-axis direction. The second device isolator 34 may be between the second doping region 26 and the third doping region 28 in the X-axis direction and/or Y-axis direction. The second device isolator 34 may be between the second doping region 26 and the bulk region 20b in the X-axis direction and/or Y-axis direction.

The first doping region 22 may be a doping region formed by doping a first conductivity type dopant to have a first conductivity type. For example, the first conductivity type dopant may be an n-type dopant, the first conductivity type may be an n-type, and the first doping region 22 may be referred to as an n-type doping region (e.g., a base n-type region).

In a plan view, the first doping region 22 may be disposed to overlap the first region, the first device isolator 32, the second region, and a portion of the second device isolator 34. For example, the first doping region 22 may include a first portion 22a, a second portion 22b, and a third portion 22c.

The first portion 22a of the first doping region 22 may be disposed in a portion (e.g., a central region) of the first region inside the first device isolator 32. More particularly, the first portion 22a of the first doping region 22 may be disposed inside the edge doping region 24 in the first region. The first portion 22a of the first doping region 22 may be a region configured to form a metal-semiconductor junction with a first electrode portion 52 of the first electrode 50 to constitute a Schottky junction.

The second portion 22b of the first doping region 22 may be disposed under (below) the second doping region 26 in the second region disposed between the first device isolator 32 and the second device isolator 34. However, the embodiments are not limited thereto. In some embodiments, in the second region disposed between the first device isolator 32 and the second device isolator 34, the second doping region 26 may be entirely disposed and the second portion 22b of the first doping region 22 may be omitted.

The third portion 22c of the first doping region 22 may be disposed under (below) the first portion 22a and/or the second portion 22b of the first doping region 22, and/or the edge doping region 24.

A depth of the first doping region 22 may be greater than a depth of the device isolator 30. The depth of the first doping region 22 may be a distance between the first surface 201 of the substrate 20 and a lower surface (or a lower end) of the first doping region 22 in a thickness direction of the substrate 20 (the Z-axis direction in the drawings), and may be, for example, a maximum depth. The depth of the device isolator 30 may be a distance between the first surface 201 of the substrate 20 and the second surface (i.e., a lower surface or a lower end) of the device isolator 30 in the thickness direction of the substrate 20 (the Z-axis direction in the drawings), and may be, for example, a maximum depth. That is, the lower surface (or the lower end) of the first doping region 22 (e.g., the lower surface (or the lower end) of the third portion 22c) may be disposed lower than the second surface (i.e., the lower surface or the lower end) of the device isolator 30.

A side surface of the first doping region 22 may connect the lower surface of the first doping region 22 (e.g., the lower surface of the third portion 22c) and a lower surface of the second device isolator 34. In the drawings, it is illustrated as an example that the side surface of the first doping region 22 includes or is formed of an inclined surface inclined to the lower surface of the first doping region 22 (e.g., the lower surface of the third portion 22c) and the lower surface of the second device isolator 34, but the embodiments are not limited thereto.

The edge doping region 24 may be a doping region formed by doping a second conductivity type dopant to have a second conductivity type different from (e.g., opposite to) the first conductivity type. For example, the second conductivity type dopant may be a p-type dopant, the second conductivity type may be a p-type, and the edge doping region 24 may be referred to as a p-type region or a field relief guard-ring. The second conductivity type dopant included in the edge doping region 24 may include or be formed of the same material as the second conductivity type dopant included in the bulk region 20b and/or the third doping region 28, or may include of be formed of a different material from the second conductivity type dopant included in the bulk region 20b and/or the third doping region 28.

The edge doping region 24 may be disposed in a portion (e.g., an edge region) of the first region inside the first device isolator 32. In some embodiments, in a plan view, the edge doping region 24 may overlap the first device isolator 32. In a plan view, the edge doping region 24 may extend along an edge of the first portion 22a of the first doping region 22 in the first region. That is, in a plan view, the edge doping region 24 may be disposed to entirely surround the first portion 22a of the first doping region 22. In a plan view, the edge doping region 24 may be disposed at a region that includes an edge of the first electrode portion 52 of the first electrode 50.

The edge doping region 24 may be the field relief guard ring that expands a depletion region in a reverse bias and relieves an edge electric field, which may be induced at the edge (edge portion or edge region) of the first electrode portion 52 of the first electrode 50.

The second doping region 26 may be a doping region formed by doping a first conductivity type dopant to have a first conductivity type. The second doping region 26 may have the first conductivity type as the first doping region 22, and may have a doping concentration higher (greater) than a doping concentration of the first doping region 22. The second doping region 26 may be disposed on the first doping region 22 (e.g., the second portion 22b) in the second region disposed between the first device isolator 32 and the second device isolator 34. The second doping region 26 may be adjacent to the first surface 201 of the substrate 20, and may be a portion that is (electrically) connected to (e.g., is in direct contact with) the second electrode 60.

For example, the first conductivity type dopant may be an n-type dopant, the first conductivity type may be an n-type, and the second doping region 26 may be referred to as an n-type doping region (e.g., a high concentration n-type doping region or an n-type contact region). The first conductivity type dopant included in the second doping region 26 may include or be formed of the same material as the first conductivity type dopant included in the first doping region 22, or may include of be formed of a different material from the first conductivity type dopant included in the first doping region 22.

The third doping region 28 may be a doping region formed by doping a second conductivity type dopant to have a second conductivity type. The third doping region 28 may have the second conductivity type as the bulk region 20b, and may have a doping concentration higher (greater) than a doping concentration of the bulk region 20b. The third doping region 28 may be disposed on the bulk region 20b in the third region disposed outside the second device isolator 34. The third doping region 28 may be adjacent to the first surface 201 of the substrate 20, and may be a portion that is (electrically) connected to (e.g., is in direct contact with) the third electrode 70.

For example, the second conductivity type dopant may be a p-type dopant, the second conductivity type may be a p-type, and the third doping region 28 may be referred to as a p-type doping region (e.g., a high concentration p-type doping region or a p-type contact region). The second conductivity type dopant included in the third doping region 28 may include or be formed of the same material as the second conductivity type dopant included in the bulk region 20b, or may include of be formed of a different material from the second conductivity type dopant included in the bulk region 20b.

The bulk region 20b may be a region of the substrate 20 where the first doping region 22, the edge doping region 24, the second doping region 26, and the third doping region 28 are not disposed, and may have the second conductivity type. The bulk region 20b may have a conductivity type different from a conductivity type of the first doping region 22 and/or the second doping region 26, and may have a doping concentration lower (less) than a doping concentration of the edge doping region 24 and/or a doping concentration of the third doping region 28. For example, the second conductivity type may be a p-type, and the bulk region 20b may be referred to a p-type region (a base p-type region or a p-type bulk region).

In the first region, the first device isolator 32, the second region, and a portion (e.g., an inner portion) of the second device isolator 34, the bulk region 20b may be disposed under the first doping region 22. For example, the first doping region 22 may be between the bulk region 20b and the first region, the first device isolator 32, the second region, and a portion (e.g., an inner portion) of the second device isolator 34 in the Z-axis direction. In another portion (e.g., an outer portion) of the second device isolator 34, the bulk region 20b may be disposed under the second device isolator 34. For example, the first doping region 22 may not be between a portion (e.g., an outer portion) of the second device isolator 34 and the bulk region 20b in the Z-axis direction. In the third region, the bulk region 20b may be disposed under the third doping region 28, and may be disposed under the device isolator 30 outside the third region. However, the embodiments are not limited thereto. A position of the bulk region 20b may be varied according to an arrangement of the first doping region 22, the edge doping region 24, the second doping region 26, and/or the third doping region 28. Herein, “inner portion” of element A may refer to a portion of element A closer than “outer portion” of element A to the center of element A in the X-axis direction and/or the Y-axis direction.

In an embodiment, the p-type dopant may include boron (B), gallium (Ga), or so on, and the n-type dopant may include phosphorous (P), arsenic (As), or so on. However, the embodiments are not limited thereto. The p-type dopant or the n-type dopant included in the bulk region 20b, the first doping region 22, the edge doping region 24, the second doping region 26, and/or the third doping region 28 may include any of various materials.

In some embodiments, at least a portion of the gate structure 40 may be disposed on (may overlap in the Z-axis direction) the edge doping region 24. The gate structure 40 may include a gate insulation layer 42 and a gate electrode 44 that are sequentially formed on the substrate 20, and may further include a spacer 46 that is disposed on a side surface of the gate insulation layer 42 and/or the gate electrode 44.

The gate insulation layer 42 may include a single layer or a plurality of layers. The gate insulation layer 42 may include or be formed of oxide, nitride, oxynitride, a lower dielectric constant material having a lower dielectric constant than silicon oxide, and/or a high dielectric constant material having a higher dielectric constant than silicon oxide. For example, the gate insulation layer 42 may include or be formed of silicon oxide, silicon nitride, and/or silicon oxynitride.

The gate electrode 44 may include or be formed of at least one of metal, a metal alloy, metal nitride, metal silicide, and/or a semiconductor material. The metal or the metal alloy that is included in the gate electrode 44 may include or be formed of Ti, W, Mo, Al, Cu, Ni, Mg, Co, Ta, Ru, Au, and/or Sr. The semiconductor material may include or be formed of a polycrystalline semiconductor material (e.g., polycrystalline silicon). The semiconductor material may be doped with an n-type or a p-type dopant. The metal nitride that is included in the gate electrode 44 may include or be formed of TiN, WN, MoN, and/or TaN. The gate electrode 44 may further include metal oxide or metal oxynitride in which the above material is oxidized.

The spacer 46 may include any of various insulating materials such as oxide, nitride, oxynitride, a low dielectric constant material, or so on. For example, the spacer 46 may include or be formed of silicon oxide, silicon nitride, and/or silicon oxynitride, or a material in which carbon is additionally included in the above material. The spacer 46 may include a single insulation layer or a plurality of insulation layers. However, the embodiments are not limited thereto. The spacer 46 may include any of various materials other than the above material.

In some embodiments, the gate structure 40 may be disposed on a portion (e.g., an outer portion) of the edge doping region 24, and might not disposed on another portion (e.g., an inner portion) of the edge doping region 24. That is, the gate structure 40 may be partially disposed on a portion of the edge doping region 24. For example, the gate structure 40 may overlap (only) a portion (e.g., an outer portion) of the edge doping region 24 in the Z-axis direction. For example, the gate structure 40 may be spaced apart from an inner edge of the edge doping region 24 by a predetermined interval and may be disposed on the outer portion of the edge doping region 24. Accordingly, an edge of the first electrode portion 52 of the first electrode 50 may be stably disposed on the another portion (e.g., the inner portion) of the edge doping region 24. For example, the first electrode portion 52 may overlap (only) the another portion (e.g., the inner portion) of the edge doping region 24 in the Z-axis direction.

In some embodiments, the gate structure 40 may further include a portion that is disposed on (that overlaps in the Z-axis direction) at least a portion (e.g., an inner portion) of the first device isolator 32. Thereby, an area of the gate structure 40 (e.g., an area of the gate electrode 44) may be efficiently secured to reduce an electrical resistance.

More particularly, the gate insulation layer 42 may be partially disposed between a portion (e.g., the outer portion) of the edge doping region 24 and the gate electrode 44 (in the Z-axis direction), and the gate electrode 44 may be disposed on the gate insulation layer 42 and the first device isolator 32. For example, a lower surface of the gate insulation layer 42 may be in contact with the portion (e.g., the outer portion) of the edge doping region 24. A lower surface of the gate electrode 44 may be in contact with the gate insulation layer 42 on the portion (e.g., the outer portion) of the edge doping region 24, and may be in contact with the first device isolator 32 on the first device isolator 32.

The gate electrode 44 may be disposed on the portion (e.g., an inner portion) of the first device isolator 32, and might not be disposed on another portion (e.g., an outer portion) of the first device isolator 32. That is, the gate electrode 44 may be partially disposed on (may partially overlap in the Z-axis direction) a portion of the first device isolator 32. For example, the gate electrode 44 may be spaced apart from an outer edge of the first device isolator 32 and may be disposed on an inner portion of the first device isolator 32. Accordingly, the gate electrode 44 and the second electrode 60 may be spaced apart from each other, and the gate electrode 44 and the second electrode 60 where different voltages are applied may be stably insulated from each other.

The spacer 46 may electrically insulate the gate electrode 44 and the substrate 20. The spacer 46 that is disposed at a side surface of the gate electrode 44 and/or the gate insulating layer 42 may include a first spacer 46a and a second spacer 46b. The first spacer 46a may be disposed at a first side (e.g., an inner side) of the gate electrode 44 (and/or the gate insulating layer 42), and the second spacer 46b may be disposed at a second side (e.g., an outer side) of the gate electrode 44 that is opposite to the first side (in the X-axis direction). That is, the first spacer 46a may constitute a first side surface (e.g., an inner side surface) 401 of the gate structure 40, and the second spacer 46b may constitute a second side surface (e.g., an outer side surface) 402 of the gate structure 40.

In a plan view, the first spacer 46a and the second spacer 46b may extend in an extension direction at the first side and the second side of the gate electrode 44, respectively. In the drawings, it is illustrated as an example that the spacers 46 are disposed at both sides (e.g., opposite sides in the X-axis direction) of the gate electrode 44, but the spacer 46 may be disposed at one side of the gate electrode 44 or the spacer 46 may be omitted.

In some embodiments, the gate structure 40 may include a first gate portion and a second gate portion. The first gate portion may be disposed on the first isolation portion 32a and a portion of the edge doping region 24 adjacent to the first isolation portion 32a. The second gate portion may be disposed on the second isolation portion 32b and a portion of the edge doping region 24 adjacent to the second isolation portion 32b. In some embodiments, the gate structure 40 may include a third gate portion and a fourth gate portion. The third gate portion may be disposed on the third isolation portion 32c and a portion of the edge doping region 24 adjacent to the third isolation portion 32c. The fourth gate portion may be disposed on the fourth isolation portion 32d and a portion of the edge doping region 24 adjacent to the fourth isolation portion 32d.

Thereby, in a plan view, the gate structure 40 may have a frame shape the same as or similar to a shape of the first device isolator 32. Thereby, the gate structure 40 may have a sufficient area and a voltage may be stably applied to the edge doping region 24 by the gate structure 40. However, the embodiments are not limited thereto. A planar shape or an arrangement of the gate structure 40 may be variously modified.

In some embodiments, the gate structure 40 may be spaced apart from the first electrode portion 52 of the first electrode 50 configured to constitute the Schottky junction with the first doping region 22. In the first surface 201 of the substrate 20, a separation portion SP may be disposed between the gate structure 40 and the first electrode portion 52 of the first electrode 50 (in the X-axis direction). Accordingly, in a plan view, the gate structure 40 may be spaced apart from the first doping region 22. More particularly, in a plan view, the first spacer 46a may be spaced apart from the first electrode portion 52 of the first electrode 50 and the separation portion SP may be disposed between the first spacer 46a and the first electrode portion 52.

By the separation portion SP, a distance between the first electrode portion 52 and a boundary (e.g., an inner edge) of the first device isolator 32 may be secured above a certain level. In case there are defects at the boundary of the first device isolator 32, by increasing the distance between the first electrode portion 52 and the boundary of the first device isolator 32 due to the separation portion SP, stability may be enhanced.

In some embodiments, a capping layer 48 may be disposed to cover (e.g., overlap in the Z-axis direction) at least the separation portion SP. For example, in the first surface 201 of the substrate 20, the capping layer 38 may entirely cover (a portion of) the edge doping region 24 exposed by the separation portion SP disposed between the first electrode portion 52 and the first spacer 46a.

The capping layer 48 may cover (e.g., overlap in the Z-axis direction) a portion of the gate structure 40 that is adjacent to the separation portion SP. For example, the capping layer 48 may entirely cover (e.g., overlap in the Z-axis direction) the first spacer 46a that is adjacent to the separation portion SP. Further, the capping layer 48 may be disposed on a portion (e.g., an inner portion) of the gate electrode 44 that is adjacent to the separation portion SP. Thereby, a process margin may be secured and the capping layer 48 may stably cover the separation portion SP and the first spacer 46a.

The capping layer 48 might not disposed on the second side surface 402 of the gate electrode 44 (e.g., the second spacer 46b). The capping layer 48 might not disposed on another portion (e.g., an outer portion) of the gate electrode 44 to provide a space where a second electrode portion 54 of the first electrode 50 is disposed. In a cross-sectional view that is perpendicular to the extension direction of the gate electrode 44, the capping layer 48 may have an asymmetrical shape with respect to the gate electrode 44. That is, the capping layer 48 may have an asymmetrical shape that is disposed on the inner portion of the gate electrode 44 and is not disposed on the outer portion of the gate electrode 44.

In the drawings, it is illustrated as an example that an area of the another portion of the gate electrode 44 where the capping layer 48 is not disposed is greater than an area of the portion of the gate electrode 44 where the capping layer 48 is disposed. Thereby, the second electrode portion 54 of the first electrode 50 may have a sufficient area to reduce an electrical resistance. However, the embodiments are not limited thereto, and the area of the portion of the gate electrode 44 where the capping layer 48 is disposed may be the same as or greater than the area of the another portion of the gate electrode 44 where the capping layer 48 is not disposed.

The capping layer 48 may cover (e.g., overlap in the Z-axis direction) the separation portion SP between the first electrode portion 52 of the first electrode 50 and the second electrode portion 54 of the first electrode 50, and a portion of the gate structure 40. The capping layer 48 may act as an alignment layer configured to control positions of the first electrode portion 52 and the second electrode portion 54 in a process of forming the first electrode 50 that includes the first electrode portion 52 and the second electrode portion 54. By the capping layer 48, the first electrode portion 52 and the second electrode portion 54 may be formed by a self-alignment. The capping layer 48 may allow the separation portion SP to be stably disposed between the first electrode portion 52 and the gate structure 40.

In some embodiments, the capping layer 48 may include a first capping portion and a second capping portion. The first capping portion may be disposed on the first gate portion and the separation portion SP that is adjacent to the first gate portion. The second capping portion may be disposed on the second gate portion and the separation portion SP that is adjacent to the second gate portion. The capping layer 48 may further include a third capping portion and a fourth capping portion. The third capping portion may be disposed on the third gate portion and the separation portion SP that is adjacent to the third gate portion. The fourth capping portion may be disposed on the fourth gate portion and the separation portion SP that is adjacent to the fourth gate portion. Thereby, in a plan view, the capping layer 48 may have a frame shape the same as or similar to a shape of the gate structure 40. The capping layer 48 may be disposed a portion between the first electrode portion 52 and the second electrode portion 54 in FIG. 2. Thereby, the capping layer 48 may extend entirely and continuously in an extension direction of the gate structure 40 and an effect by the capping layer 48 may be sufficiently achieved. However, the embodiments are not limited thereto. A planar shape or an arrangement of the capping layer 48 may be variously modified.

The capping layer 48 may include a material different from a material of the spacer 46 and may be easily patterned to have a desirable shape. The capping layer 48 may include or be formed of a material capable of preventing of penetration of hydrogen into the edge doping region 24 or protecting the edge doping region 24. For example, the capping layer 48 may include or be formed of nitride (e.g., silicon nitride). However, the embodiments are not limited thereto, and the capping layer 48 may include any of various materials.

In some embodiments, the first electrode 50 may be (electrically) connected to the first doping region 22, the edge doping region 24, and the gate structure 40. The second electrode 60 may be (electrically) connected to the second doping region 26. The third electrode 70 may be (electrically) connected to the third doping region 28. The wiring portion 80 may include a wiring layer 82w and/or 84w that is (electrically) connected to the first electrode 50, the second electrode 60, and the third electrode 70.

The first electrode 50 may include a first electrode portion 52 and a second electrode portion 54. The first electrode portion 52 may be disposed on the first doping region 22 and the edge doping region 24 and constitute the Schottky junction with the first doping region 22. The second electrode portion 54 may be (electrically) connected to the gate structure 40 (e.g., the gate electrode 44).

The first electrode portion 52 may be disposed on the first portion 22a of the first doping region 22 that is adjacent to the first surface 201 of the substrate 20, and a portion (e.g., an inner portion) of the edge doping region 24. In a plan view, the first electrode portion 52 may overlap an entire portion of the first portion 22a of the first doping region 22 (in the Z-axis direction), and an edge portion (an outer portion) of the first electrode portion 52 may be disposed on (may overlap in the Z-axis direction) the edge doping region 24. That is, in a plan view, the edge portion (the outer portion) of the first electrode portion 52 may be disposed between an inner edge 241 and an outer edge 242 of the edge doping region 24.

In a plan view, the first electrode portion 52 may have a symmetrical shape with respect to the first portion 22a of the first doping region 22 (in the X-axis direction and/or the Y-axis direction). That is, in the first direction (the X-axis direction in the drawings), a first edge (e.g., a left edge in a plan view) of the first portion 22a and a first edge (e.g., a left edge in the plan view) of the first electrode portion 52 that are adjacent to each other may be spaced apart from each other by a first distance, and a second edge (e.g., a right edge in the plan view) of the first portion 22a and a second edge (e.g., a right edge in the plan view) of the first electrode portion 52 that are adjacent to each other may be spaced apart from each other by the first distance. In the second direction (the Y-axis direction in the drawings), a third edge (e.g., an upper edge in the plan view) of the first portion 22a and a third edge (e.g., an upper edge in the plan view) of the first electrode portion 52 that are adjacent to each other may be spaced apart from each other by the first distance, and a fourth edge (e.g., a lower edge in the plan view) of the first portion 22a and a fourth edge (e.g., a lower edge in the plan view) of the first electrode portion 52 that are adjacent to each other may be spaced apart from each other by the first distance. Accordingly, the first electrode portion 52 may have a symmetrical shape with respect to the first portion 22a of the first doping region 22 in each of the first direction and the second direction.

In a plan view, the first electrode portion 52 may be entirely disposed on the first portion 22a of the first doping region 22, and an area of the Schottky junction may be efficiently secured. For example, the first portion 22a of the first doping region 22 may be entirely overlapped (covered) by the first electrode portion 52 in the Z-axis direction. In a plan view, the edge of the first electrode portion 52 may be disposed on the edge doping region 24, and the edge doping region 24, which is the field relief guard ring, may effectively relieve the edge electric field that may be induced at the edge of the first electrode portion 52.

For example, the first electrode portion 52 may be in contact with the first portion 22a of the first doping region 22, and be in contact with the edge doping region 24 that has a uniform doping concentration in an entire portion. That is, in some embodiments, there may be no additional doping region of a comparative example. In the comparative example, the additional doping region may be on or above an edge doping region, and may have a high doping concentration higher than a doping concentration of the edge doping region to relieve problems that may be induced when an edge of a first electrode and the edge doping region are in contact with each other. Thereby, a manufacturing process of some embodiments of the present inventive concepts may be simplified.

The second electrode portion 54 may be disposed on (may overlap in the Z-axis direction) a portion (e.g., an outer portion) of the gate electrode 44, and might not be disposed on another portion (e.g., an inner portion) of the gate electrode 44. That is, the second electrode portion 54 may be partially disposed on the portion (e.g., the outer portion) of the gate electrode 44. For example, the second electrode portion 54 may be spaced apart from an inner edge of the gate electrode 44 by a predetermined interval and may be disposed on the outer portion of the gate electrode 44.

More particularly, an inner edge of the second electrode portion 54 and the inner edge of the gate electrode 44 may be spaced apart from each other by a second distance, and an outer edge of the second electrode portion 54 and an outer edge of the gate electrode 44 may be adjacent to each other (e.g., aligned each other in the Z-axis direction) or may be spaced apart from each other by a distance less than the second distance. That is, in a cross-sectional view that is perpendicular to the extension direction of the gate electrode 44, the second electrode portion 54 may have an asymmetrical shape with respect to the gate electrode 44.

As in the above, the gate insulation layer 42 may be disposed in a portion of the gate structure 40 that is adjacent to the edge doping region 24, and the second electrode portion 54 may be spaced part from the first side surface 401 of the gate structure 40 adjacent to the edge doping region 24 and may be adjacent to the second side surface 402 of the gate structure 40. Accordingly, in a plan view, the gate insulation layer 42 that is disposed on the lower surface of the gate electrode 44 may be opposite to the second electrode portion 54 that is disposed on the upper surface of the gate electrode 44 (in the Z-axis direction).

In a plan view, the second electrode portion 54 may include a portion that overlaps the gate insulation layer 42 and/or the edge doping region 24 (in the Z-axis direction). Thereby, an electric field may be stably applied to the edge doping region 24 by a voltage applied through the second electrode portion 54. However, the embodiments are not limited thereto. The second electrode portion 54 might not include the portion that overlaps the gate insulation layer 42 or the edge doping region 24 in a plan view. Even in this instance, the electric field may be applied to the edge doping region 24 through the gate electrode 44.

For example, the first electrode portion 52 may be in contact with the first portion 22a of the first doping region 22 and the edge doping region 24, and the second electrode portion 54 may be in contact with the gate electrode 44. However, the embodiments are not limited thereto. In some embodiments, an additional layer may be disposed between the first portion 22a of the first doping region 22 and the first electrode portion 52 and/or and between the edge doping region 24 and the first electrode portion 52, and/or an additional layer may be disposed between the second electrode portion 54 and the gate electrode 44.

In some embodiments, in a plan view, the first electrode portion 52 and the second electrode portion 54 may be spaced apart from each other, and the first electrode portion 52 and the second electrode portion 54 may be (electrically) connected to each other by the wiring portion 80. Thereby, the same voltage (an equal voltage) may be applied to the first electrode portion 52 and the second electrode portion 54. This will be described in more detail after the wiring portion 80 is described.

The second electrode 60 may be (electrically) connected to the second doping region 26 that is adjacent to the first surface 201 of the substrate 20. For example, the second electrode 60 may be in contact with to the second doping region 26 that is adjacent to the first surface 201 of the substrate 20. However, the embodiments are not limited thereto. In some embodiments, an additional layer may be disposed between the second electrode 60 and the second doping region 26.

The third electrode 70 may be (electrically) connected to the third doping region 28 that is adjacent to the first surface 201 of the substrate 20. The third electrode 70 may apply a ground voltage to the third doping region 28 and/or the bulk region 20b. For example, the third electrode 70 may be in contact with the third doping region 28 that is adjacent to the first surface 201 of the substrate 20. However, the embodiments are not limited thereto. In some embodiments, an additional layer may be disposed between the third electrode 70 and the third doping region 28.

In some embodiments, the first electrode portion 52 and the second electrode portion 54 of the first electrode 50 may be formed by the same process and may include the same material. Thereby, a manufacturing process may be simplified. The gate electrode 44 may be formed separately from the first electrode portion 52 and the second electrode portion 54 of the first electrode 50, and may include a different material from the first electrode portion 52 and the second electrode portion 54 of the first electrode 50.

For example, the second electrode 60 and/or the third electrode 70 may be formed by the same process as the first electrode portion 52 and the second electrode portion 54 of the first electrode 50, and may include the same material as the first electrode portion 52 and the second electrode portion 54 of the first electrode 50. Thereby, a manufacturing process may be simplified. In some embodiments, the second electrode 60 and/or the third electrode 70 may be formed by the different process from the first electrode portion 52 and the second electrode portion 54 of the first electrode 50, or may include a different material from the first electrode portion 52 and the second electrode portion 54 of the first electrode 50.

The first electrode 50, the second electrode 60, and/or the third electrode 70 may include or be formed of metal, for example, metal silicide. The first electrode 50, the second electrode 60, and/or the third electrode 70 may include or be formed of cobalt, tungsten, titanium, tantalum, platinum, gold, or so on, for example, cobalt silicide, tungsten silicide, titanium silicide, tantalum silicide, platinum silicide, gold silicide, so on. When the first electrode 50, the second electrode 60, and/or the third electrode 70 includes or is formed of the metal silicide, an electrical resistance with the first doping region 22, the second doping region 26, and/or the third doping region 28 in the substrate 20 may be reduced. However, the embodiments are not limited thereto, and the first electrode 50, the second electrode 60, and/or the third electrode 70 may include any of various materials.

In some embodiments, the first electrode 50 may be an anode electrode, the second electrode 60 may be a cathode electrode, and the third electrode 70 may be a ground electrode.

The wiring portion 80 may be disposed on the first surface 201 of the substrate 20, the gate structure 40, the first electrode 50, the second electrode 60, and the third electrode 70. The wiring portion 80 may include a first wiring layer 82w and a second wiring layer 84w. The first wiring layer 82w may be (electrically) connected to the first electrode 50, the second electrode 60, and/or the third electrode 70 through a first contact via 82v that extends in (e.g., passes through or penetrates) a first interlayer insulation layer 82i. The second wiring layer 84w may be (electrically) connected to the first wiring layer 82w through a second contact via 84v that extends in (e.g., passes through or penetrates) a second interlayer insulation layer 84i.

The first contact via 82v may be formed by the same process as the first wiring layer 82w, or may be formed by a different process from the first wiring layer 82w. The second contact via 84v may be formed by the same process as the second wiring layer 84w, or may be formed by a different process from the second wiring layer 84w.

The first wiring layer 82w, the second wiring layer 84w, the first contact via 82v, or the second contact via 84v may include any of various conductive materials. The first wiring layer 82w, the second wiring layer 84w, the first contact via 82v, and/or the second contact via 84v may include or be formed of metal, a metal alloy, metal nitride, metal silicide, and/or a doped semiconductor material. The metal or the metal alloy may include tungsten, molybdenum, aluminum, copper, and/or cobalt, and the metal nitride may include tungsten nitride, molybdenum nitride, titanium nitride, and/or tantalum nitride. The first wiring layer 82w, the second wiring layer 84w, the first contact via 82v, and/or the second contact via 84v may further include metal oxide or metal oxynitride in which the above material is oxidized. The first wiring layer 82w, the second wiring layer 84w, the first contact via 82v, and/or the second contact via 84v may include a single layer or a plurality of layers.

The first interlayer insulation layer 82i and/or the second interlayer insulation layer 84i may include any of various insulating materials. For example, the first interlayer insulation layer 82i and/or the second interlayer insulation layer 84i may include or be formed of silicon oxide, silicon nitride, and/or silicon oxynitride. A boundary between the device isolator 30 and the first interlayer insulation layer 82i and/or a boundary between the first interlayer insulation layer 82i and the second interlayer insulation layer 84i may be seen or confirmed or might not be seen or confirmed in a final structure.

In some embodiments, the first wiring layer 82w may include a first electrode connection portion that is (electrically) connected to the first electrode 50 through the first contact via 82v. The first electrode connection portion may include a first wiring 822 and a second wiring 824. The first wiring 822 may be (electrically) connected to the first electrode portion 52. The second wiring 824 may be (electrically) connected to the second electrode portion 54 through the first contact via 82v and may be spaced apart from the first wiring 822. For example, the first wiring 822 may include a plurality of portions that are spaced apart from each other. Thereby, the first wiring 822 and the second wiring 824 may have widths below certain levels and may be easily formed by various processes. For example, the first wiring layer 82w and the first contact via 82v may be formed by a dual damascene process and a process may be simplified.

The second wiring layer 84w may include a common connection portion 842 that is (electrically) connected to the first electrode connection portion (e.g., the first wiring 822 and the second wiring 824) through the second contact via 84v. In a plan view, the common connection portion 842 may be disposed entirely in a region including portions where the first wiring 822 and the second wiring 824 are disposed. That is, a plurality of second contact vias 84v that are (electrically) connected to the first wiring 822 and the second wiring 824 may be (electrically) connected together to the common connection portion 842 of a single body. Thereby, the same voltage (an equal voltage) may be easily applied to the first electrode portion 52 and the second electrode portion 54 of the first electrode 50.

The first wiring layer 82w may include a second electrode connection portion and a third electrode connection portion. The second electrode connection portion may be (electrically) connected to the second electrode 60 through the first contact via 82v. The third electrode connection portion may be (electrically) connected to the third electrode 70 through the first contact via 82v. The second wiring layer 84w may include a portion that is (electrically) connected to the second electrode connection portion through the second contact via 84v and a portion that is (electrically) connected to the third electrode connection portion through the second contact via 84v. The first wiring layer 82w may further include a wiring other than the first electrode connection portion, the second electrode connection portion, and the third electrode connection portion. The second wiring layer 84w may further include a wiring other than the common connection portion 842, the portion (electrically) connected to the second electrode connection portion, and the portion (electrically) connected to the third electrode connection portion.

In some embodiments, it is illustrated as an example that the same voltage (an equal voltage) is applied to the first electrode portion 52 and the second electrode portion 54 using the common connection portion 842 of the second wiring layer 84w (electrically) connected to the first wiring 822 and the second wiring 824 of the first wiring layer 82w. However, the embodiments are not limited thereto. In some embodiments, the first wiring layer 82w may include a common connection portion (electrically) connected to the first electrode portion 52 and the second electrode portion 54. In some embodiments, even when the first wiring layer 82w or the second wiring layer 84w might not include the common connection portion, the wiring portion 80 may have a structure configured to apply the same voltage (an equal voltage) to the first electrode portion 52 and the second electrode portion 54 of the first electrode 50. Other various modifications are possible.

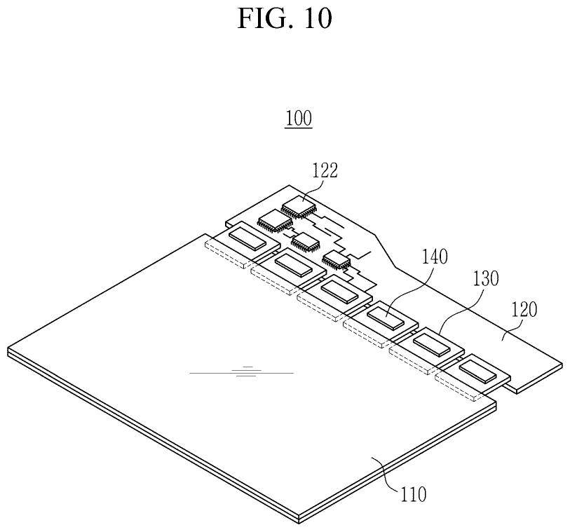

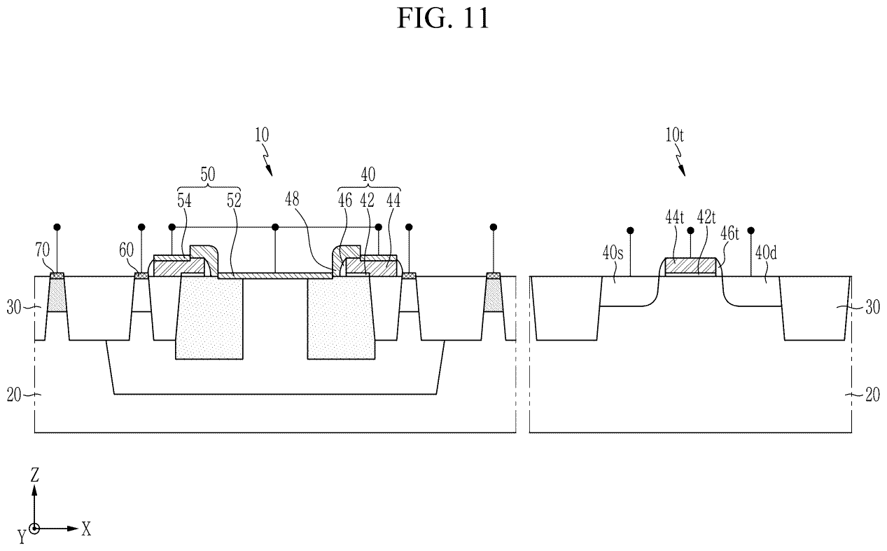

In some embodiments, the first electrode 50, the second electrode 60, and/or the third electrode 70, and the wiring portion 80 that applies voltage thereto may be disposed together at the side of the first surface 201 of the substrate 20. Thereby, a structure that applies the voltage to the first electrode 50, the second electrode 60, and/or the third electrode 70 may be simplified. Thereby, the semiconductor device 10 according to some embodiments may be embedded in an electronic device together with a semiconductor device or a circuit element other than the semiconductor device 10. That is, at the substrate 20 included in the electronic device, the semiconductor device 10 according to some embodiments, and a semiconductor device or a circuit element that has a different structure from the semiconductor device 10 may be formed together. This will be described later in more detail with referent to FIG. 10 and FIG. 11.

In some embodiments, it is illustrated or described as an example that the second electrode 60 and/or the third electrode 70 is disposed on the same position with the first electrode 50 on the first surface 201 of the substrate 20 in the thickness direction (e.g., the Z-axis direction) of the semiconductor device 10, or the second electrode 60 and/or the third electrode 70 is formed by the same process as the first electrode 50. However, the second electrode 60 and/or the third electrode 70 may be disposed on a different position from the first electrode 50 in the thickness direction of the semiconductor device 10 or may be formed by a different process from the first electrode 50. For example, a portion that is (electrically) connected to the second doping region 26 and applies a voltage to the second doping region 26 may be regarded as the second electrode 60, and a portion that is (electrically) connected to the third doping region 28 and applies a voltage to the third doping region 28 may be regarded as the third electrode 70. For example, the first contact via 82v may be in contact with the second doping region 26 and/or the third doping region 28. In this instance, the first contact via 82v may be the second electrode 60 and/or the third electrode 70.

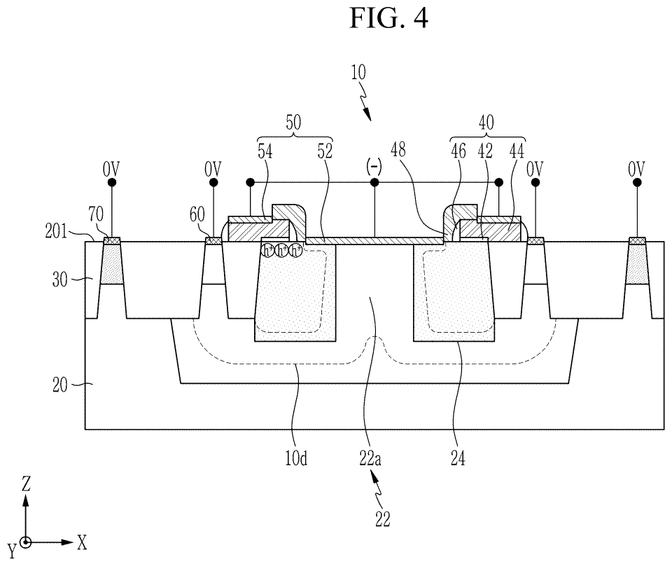

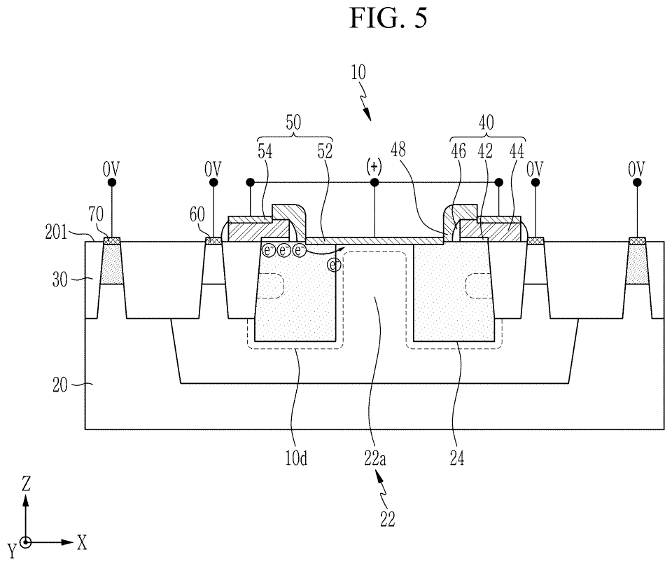

An operation of a semiconductor device 10 according to some embodiments will be described in detail with reference to FIG. 4 and FIG. 5.

FIG. 4 schematically illustrates a depletion region and holes of a semiconductor device 10 according to some embodiments in a reverse bias. FIG. 5 schematically illustrates a depletion region and electrodes of the semiconductor device 10 according to some embodiments in a forward bias. For a clear understanding and simple illustration, in FIG. 4 and FIG. 5, a shape of a wiring portion 80 (refer to FIG. 1) is conceptually illustrated.

As illustrated in FIG. 4, in a reverse bias, a negative voltage may be applied to a first electrode 50 (i.e., an anode electrode), and voltages of a second electrode 60 (i.e., a cathode electrode) and a third electrode 70 (i.e., a ground electrode) may be zero (0). The negative voltage and the zero (0) voltage may be examples for explanation, the embodiments are not limited thereto.

As illustrated in FIG. 4, when the negative voltage is applied to the first electrode 50, a semiconductor device 10 may be in a turn-off state by the negative voltage applied to the first electrode portion 52. By an edge doping region 24 of a field relief guard ring, a depletion region 10d may be expanded and an edge electric field that may be induced at an edge of a first electrode portion 52 may be relived. By the negative voltage applied to the first electrode portion 52, holes may be accumulated in a portion of the edge doping region 24 (i.e., a portion of the edge doping region 24 that is adjacent to a first surface 201 of a substrate 20). Thereby, in the reverse bias, a threshold voltage may increase.

As illustrated in FIG. 5, in a forward bias, a positive voltage may be applied to a first electrode 50 (i.e., an anode electrode), and voltages of a second electrode 60 (i.e., a cathode electrode) and a third electrode 70 (i.e., a ground electrode) may be zero (0). The positive voltage and the zero (0) voltage may be examples for explanation, the embodiments are not limited thereto.

When the positive voltage is applied to the first electrode 50, a semiconductor device 10 may be in a turn-on state by the positive voltage applied to a first electrode portion 52. Accordingly, current may flow. The semiconductor device 10 may be a Schottky barrier diode, and may have a fast switching property and have a relatively low turn-on voltage.

When the positive voltage is applied to the first electrode 50, a depletion region 10d may be expanded and an inversion layer may be formed by the positive voltage applied to the gate electrode 44 through the second electrode portion 54. For example, the depletion region 10d may have a predetermined thickness under the first portion 22a of the first doping region 22 and along an edge of the edge doping region 24. By the positive voltage applied to the gate electrode 44, electrons may be accumulated in a portion of the edge doping region 24 (i.e., a portion of the edge doping region 24 that is adjacent to a first surface 201 of a substrate 20). The electrons in the portion of the edge doping region 24 (i.e., the portion of the edge doping region 24 that is adjacent to the first surface 201 of the substrate 20) may easily move to a portion of the first portion 22a of the first doping region 22 that is adjacent to the first electrode portion 52 (i.e., a portion of the first doping region 22 that is adjacent to the first surface 201 of the substrate 20). By the expansion of the depletion region 10d and the electrons accumulation due to the positive voltage applied to the gate electrode 44, a current density of the semiconductor device 10 may increase in the forward bias.

That is, in some embodiments, the gate structure 40 that is an insulated gate including the gate insulation layer 42 and the gate electrode 44 may be disposed on the edge doping region 24 of the field relief guard ring. Accordingly, degradation of a forward current property that may be induced when the edge doping region 24 is included may be prevented. Accordingly, the semiconductor device 10 may have enhanced current capability and have enhanced performance.

According to some embodiments, by the edge doping region 24 of the field relief guard ring, the threshold voltage in the reverse bias may increase. The edge doping region 24 may be disposed in the substrate 20, and the edge doping region 24 may be easily formed and the edge doping region 24 may be disposed in an entire portion where the edge of the first electrode portion 52 of the first electrode 50 is disposed. The gate structure 40 may be disposed on the edge doping region 24 and increase the current density in the forward bias.

Accordingly, the current density in the forward bias may increase while maintaining the threshold voltage in the reverse bias high, and performance of the semiconductor device 10 may be enhanced.

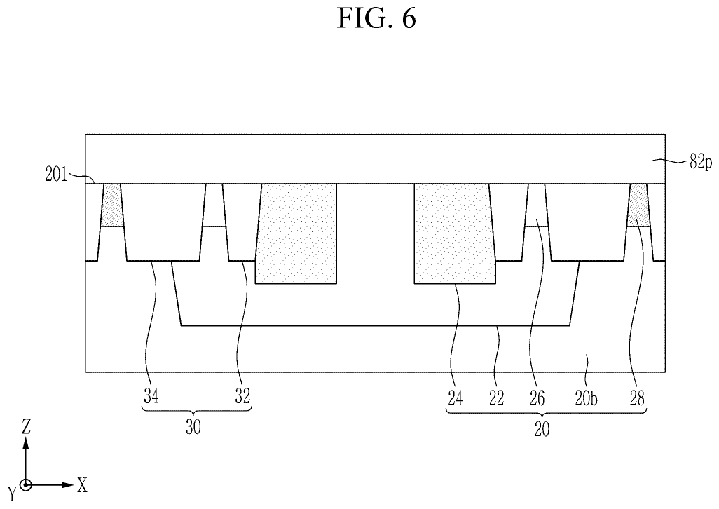

Hereinafter, a manufacturing method of a semiconductor device 10 will be described in more detail with reference to FIGS. 6 to 9. To the extent that an element is not described in detail below, it may be understood that the element is at least similar to a corresponding element that has been described elsewhere within the present disclosure. A portion which is not described in the above will be described in detail.

FIGS. 6 to 9 are cross-sectional views that illustrate a manufacturing method of a semiconductor device 10. FIGS. 6 to 9 illustrate a portion corresponding to a portion in FIG. 1.

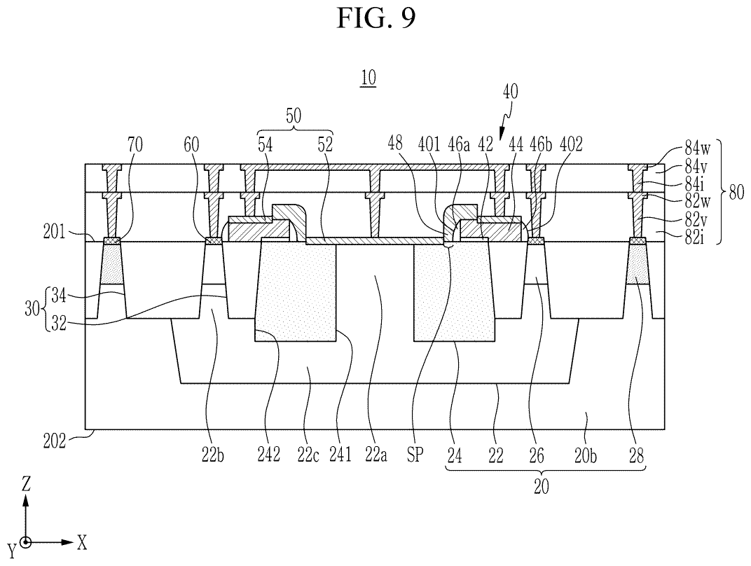

As illustrated in FIG. 6, a first doping region 22, an edge doping region 24, a second doping region 26, and a third doping region 28 may be formed at (in) a substrate 20, and a device isolator 30 and a preliminary interlayer insulation layer 82p may be formed. The preliminary interlayer insulation layer 82p may be a portion of a first interlayer insulation layer 82i (refer to FIG. 9).

The first doping region 22, the edge doping region 24, the second doping region 26, or the third doping region 28 may be formed by doping a portion of the substrate 20 at a side of a first surface 201 of the substrate 20. A doping process may be performed by any of various processes (e.g., an ion implantation process or so on).

A mask pattern may be formed on the first surface 201 of the substrate 20. The mask pattern may have an opening that exposes a region correspond to the device isolator 30. A shallow trench may be formed by etching a portion of the substrate 20 exposed through the opening of the mask pattern. The mask pattern may be removed or the mask pattern might not be removed. At least a portion of the shallow trench may be filled with an insulation layer to form the device isolator 30, and the preliminary interlayer insulation layer 82p may be formed.

In some embodiments, the device isolator 30 and/or the preliminary interlayer insulation layer 82p may be formed by any of various processes (e.g., a deposition process). For example, after the device isolator 30 may be formed, the preliminary interlayer insulation layer 82p may be formed. In some embodiments, the preliminary interlayer insulation layer 82p may be formed to fill the shallow trench for the device isolator 30, thereby forming the device isolator 30 and the preliminary interlayer insulation layer 82p together.

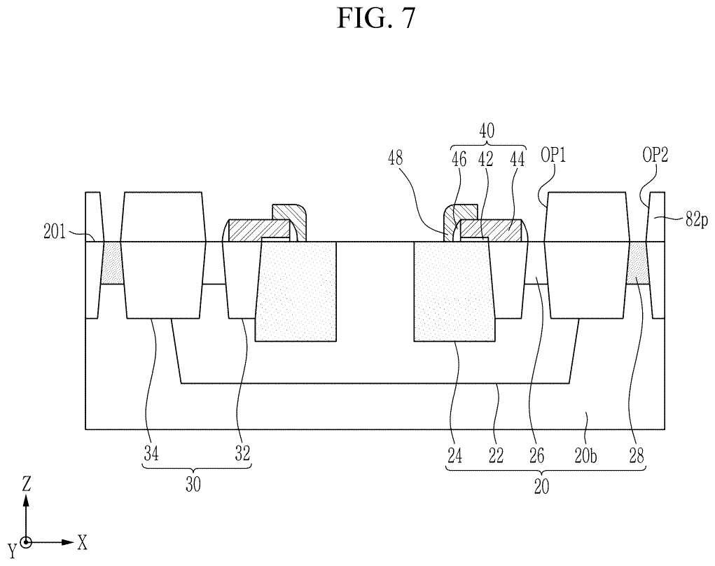

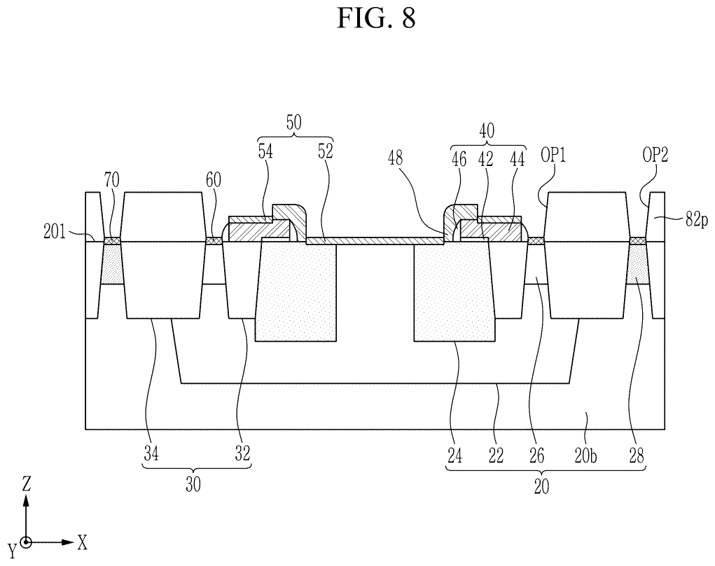

Subsequently, as illustrated in FIG. 7, a gate structure 40 and a capping layer 48 may be formed, and openings OP1 and OP2 for a first electrode 50 (refer to FIG. 8), a second electrode 60 (refer to FIG. 8), a third electrode 70 (refer to FIG. 8) may be formed.

For example, a portion of the preliminary interlayer insulation layer 82p where at least a gate insulation layer 42 and a gate electrode 44 will be disposed may be removed, and the gate insulation layer 42 and the gate electrode 44 may be formed. The gate insulation layer 42 may be formed by a thermal oxidation process or so on. The gate insulation layer 42 may include or be formed of silicon oxide. However, the embodiments are not limited thereto, and the gate insulation layer 42 may be formed by any of various processes. The gate electrode 44 may be formed by any of various processes (e.g., a deposition process).

After the gate insulation layer 42 and the gate electrode 44 are formed, a spacer 46 and the capping layer 48 may be formed.

For example, the spacer 46 may be formed by forming a preliminary spacer layer to entirely cover the first surface 201 of the substrate 20, the gate insulation layer 42, and the gate electrode 44 and etching a portion of the preliminary spacer layer. The preliminary spacer layer may be formed by any of various processes (e.g., a deposition process). A process of etching the portion of the preliminary spacer layer may be performed by any of various processes (e.g., a dry etching process, a wet etching process, or so on).

For example, the capping layer 48 may be formed by forming a preliminary capping layer to entirely cover the first surface 201 of the substrate 20 and the gate structure 40 and etching a portion of the preliminary capping layer. The preliminary capping layer may be formed by any of various processes (e.g., a deposition process). A process of etching the portion of the preliminary capping layer may be performed by any of various processes (e.g., a dry etching process, a wet etching process, or so on). The capping layer 48 may be formed to cover a portion of the substrate 20 that is adjacent to the gate structure 40, a first side surface of the gate structure 40, and a portion of an upper surface of the gate electrode 44. The portion of the substrate 20 that is adjacent to the gate structure 40 may be a separation portion SP (refer to FIG. 1) disposed between a first electrode portion 52 (refer to FIG. 8) and the gate structure 40.

The openings OP1 and OP2 may be formed by any of various processes (e.g., a dry etching process, a wet etching process, or so on). A process of forming the openings OP1 and OP2 may have any of various process sequence, or the openings OP1 and OP2 may be formed in a process of forming another portion.

For example, a portion of the preliminary interlayer insulation layer 82p where the gate insulation layer 42 and the gate electrode 44 will be disposed may be partially removed, and the gate insulation layer 42 and the gate electrode 44 may be formed in the partially removed portion. Thereby, the gate insulation layer 42 and the gate electrode 44 may be formed by an easy process and a process may be simplified. After that, portions of the preliminary interlayer insulation layer 82p corresponding to the openings OP1 and OP2 may be removed, and the spacer 46 and the capping layer 48 may be formed.

In some embodiments, after portions of the preliminary interlayer insulation layer 82p corresponding to the openings OP1 and OP2 may be removed, and the gate insulation layer 42 and the gate electrode 44 may be formed. In this instance, after the gate insulation layer 42 and the gate electrode 44 may be formed, a patterning process may be performed. The patterning process of the gate insulation layer 42 and the gate electrode 44 may be performed using any of various processes (e.g., a photolithography process). After that, the spacer 46 and the capping layer 48 may be formed.

Subsequently, as illustrated in FIG. 8, a first electrode 50 that includes a first electrode portion 52 and a second electrode portion 54 may be formed. In a process of forming the first electrode 50, the second electrode 60 and the third electrode 70 may be formed.

In some embodiments, the first electrode portion 52, the second electrode portion 54, and the second electrode 60 may be formed on a portion where the capping layer 48 is not disposed in a portions exposed through the first opening OP1. For example, the first electrode portion 52 may be formed on the edge doping region 24 in an inner portion of the capping layer 48, the second electrode portion 54 may be formed on the gate electrode 44 in an outer portion of the capping layer 48, and the second electrode 60 may be formed on the first surface 201 of the substrate 20 (e.g., on a second doping region 26) exposed through the first opening OP1 in an outer portion of the gate structure 40. The third electrode 70 may be formed on the first surface 201 of the substrate 20 (e.g., on the third doping region 28) exposed through the second opening OP2.

The first electrode 50, the second electrode 60, and/or the third electrode 70 may be formed by any of various processes. For example, the first electrode 50, the second electrode 60, and/or the third electrode 70 may be formed by depositing a metal material and performing an annealing process. Thereby, the first electrode 50, the second electrode 60, and/or the third electrode 70 may be formed on the substrate 20 and/or the gate electrode 44 that includes a semiconductor material. Thereby, there may be no need to perform a patterning process, and the first electrode 50, the second electrode 60, and/or the third electrode 70 ay be formed by an easy process.

In FIG. 8, it is illustrated as an example that the second electrode 60 and/or the third electrode 70 are formed in the process of forming the first electrode 50, but the embodiments are not limited thereto. The second electrode 60 and/or the third electrode 70 may be formed in a process other than the process of forming the first electrode 50, or a process of forming the second electrode 60 and/or the third electrode 70 may be omitted.

Subsequently, as illustrated in FIG. 9, a wiring portion 80 that is (electrically) connected to the first electrode 50, the second electrode 60, and the third electrode 70 may be formed on the first surface 201 of the substrate 20.

The wiring portion 80 may include a first wiring layer 82w and a second wiring layer 84w. The first wiring layer 82w may be (electrically) connected to the first electrode 50, the second electrode 60, and/or the third electrode 70 through a first contact via 82v that extends in (e.g., passes through or penetrates) a first interlayer insulation layer 82i. The second wiring layer 84w may be (electrically) connected to the first wiring layer 82w through a second contact via 84v that extends in (e.g., passes through or penetrates) a second interlayer insulation layer 84i. The first interlayer insulation layer 82i may be formed by filling an insulating material in at least the openings OP1 and OP2 (refer to FIG. 8) of the preliminary interlayer insulation layer 82p (refer to FIG. 8). A process of forming the wiring portion 80 may be performed by any of various processes.

According to some embodiments, the semiconductor device 10 having enhanced performance may be formed by an easy process and productivity may be enhanced.

In the drawings, a boundary between the device isolator 30 and the preliminary interlayer insulation layer 82p or a boundary between the device isolator 30 and the first interlayer insulation layer 82i is illustrated as an example for a clear understanding. In a final structure, the boundary between the device isolator 30 and the first interlayer insulation layer 82i might not be existed, seen, or confirmed.

Hereinafter, with reference to FIG. 10 and FIG. 11, an electronic device including a semiconductor device 10 according to some embodiments will be described in detail. To the extent that an element is not described in detail below, it may be understood that the element is at least similar to a corresponding element that has been described elsewhere within the present disclosure. A portion which is not described in the above will be described in detail.

FIG. 10 is a perspective view that illustrates an example of an electronic device including a semiconductor device 10 according to some embodiments. FIG. 11 is a cross-sectional view that conceptually illustrates a plurality of semiconductor devices included in the electronic device illustrated in FIG. 10. In FIG. 11, it is illustrated as an example that the plurality of semiconductor devices include a semiconductor device 10 according to some embodiments and a transistor 10t. In FIG. 11, the semiconductor device 10 and the transistor 10t are conceptually illustrated.

Referring to FIG. 10 and FIG. 11, a display module 100 may include the display panel 110, a printed circuit board 120, a film package 130, and a display driver integrated circuit (DDI) 140.

The display module 100 according to some embodiments may be included in any of various devices or apparatus. For example, the display module 100 may be included in at least one of an electronic device for vehicle, a home appliance, a mobile phone, a personal computer, a tablet, an e-book reader, a desktop PC, a personal digital assistant (PDA), a camera, a server, a mobile medical device, a wearable device, a security device, or internet of things (IoT). However, the embodiments are not limited thereto.

The display panel 110 may include any of various panels capable of displaying images. For example, the display panel 110 may include a liquid crystal display (LCD), a light emitting diode (LED) display, an organic light emitting diode (OLED) display, a plasma display panel (PDP), or so on. However, the embodiments are not limited thereto, and the display panel 110 may have any of various structures or types.

A circuit element 122 configured to provide an electric signal to the display driver integrated circuit 140 may be mounted on the printed circuit board 120. The film package 130 may connect the display panel 110 and the printed circuit board 120.

The display driver integrated circuit 140 may include a power supply, a logic circuit, a memory, an interface, or so on. The display driver integrated circuit 140 may include a transistor 10t, a p-n junction diode, a Schottky barrier diode, or so on.

In some embodiments, it is illustrated as an example that the film package 130 includes the display driver integrated circuit 140, but the embodiments are not limited thereto. The display driver integrated circuit 140 may be included in the display panel 110, the printed circuit board 120, or so on. Other various modifications are possible.

A semiconductor device 10 according to some embodiments may be the Schottky barrier diode included in the display driver integrated circuit 140. That is, an electronic device including the semiconductor device 10 according to some embodiments may be the display driver integrated circuit 140. However, the electronic device including the semiconductor device 10 may be any of various electronic devices or integrated circuits other than the display driver integrated circuit 140.

In some embodiments, the semiconductor device 10 (e.g., a first semiconductor device) may be embedded in an electronic device or an integrated circuit (e.g., the display driver integrated circuit 140). For example, the semiconductor device 10 (e.g., the first semiconductor device) may be formed together a second semiconductor device. The second semiconductor device may be included in the electronic device or the integrated circuit and have a different structure from the semiconductor device 10. The second semiconductor device may include the transistor 10t, the p-n junction diode, or so on.

In FIG. 11, it is illustrated as an example that the second semiconductor device is the transistor 10t that is disposed on or at the substrate 20 where the semiconductor device 10 (e.g., the first semiconductor device) is disposed. In FIG. 11, it is illustrated as an example that the transistor 10t includes a gate insulation layer 42t and a gate electrode 44t on the substrate 20, a spacer 46t on a side surface of the gate insulation layer 42t and the gate electrode 44t on the substrate 20, and source and drain regions 40s and 40d that are disposed in the substrate 20 at both sides (e.g., opposite sides in the X-axis direction) of the gate insulation layer 42t, the gate electrode 44t, and the spacer 46t. However, the embodiments are not limited thereto, and a structure of the transistor 10t may be variously modified. Various second semiconductor devices other than the transistor 10t may be disposed on or at the substrate 20 where the semiconductor device 10 (e.g., the first semiconductor device) is disposed.

For example, at least a portion of a process of forming the gate insulation layer 42t, the gate electrode 44t, and/or the spacer 46t included in the transistor 10t and at least a portion of a process of forming a gate insulation layer 42, a gate electrode 44, and/or a spacer 46 included in the semiconductor device 10 may be shared (e.g., may be the same or may be performed together). However, the embodiments are not limited thereto, and the gate insulation layer 42t, the gate electrode 44t and/or the spacer 46t included in the transistor 10t may be formed separately from the process of forming the gate insulation layer 42, the gate electrode 44 and/or the spacer 46 included in the semiconductor device 10 may be shared.

In the electronic device or integrated circuit (e.g., the display driver integrated circuit 140), the semiconductor device 10 of the Schottky barrier diode may perform various roles.

The semiconductor device 10 of the Schottky barrier diode may have an enhance property in a high-frequency range and may be applied to an electronic circuit in a high-frequency range, or may be act as a high-speed detection device or an electro static discharge (ESD) device. For example, in the display driver integrated circuit 140, the semiconductor device 10 may be a latch-up prevention device. The latch-up prevention device may prevent a latch-up phenomenon in which a parasitic thyristor (a parasitic silicon controlled rectifier (a parasitic SCR)) is unintentionally turned on and current flows during operation of the display module 100.

In some embodiments, the semiconductor device 10 of the Schottky barrier diode may be embedded in the electronic device or the integrated circuit (e.g., the display driver integrated circuit 140), and a structure of the electronic device or the integrated circuit may be simplified. Thereby, product competitiveness may be enhanced compared to a comparative example in which a semiconductor device of a Schottky barrier diode or a latch-up prevention device is separately formed and externally mounted in an electronic device or an integrated circuit.

While some examples have been described in connection with what is presently considered to be some practical embodiments, it is to be understood that the disclosure is not limited to the disclosed embodiments, and that the disclosure is intended to cover various modifications and equivalent arrangements included within the scope of the appended claims.

What is claimed is:

1. A semiconductor device, comprising:
a substrate that includes a first doping region having a first conductivity type, an edge doping region having a second conductivity type that is different from the first conductivity type, and a second doping region having the first conductivity type, wherein the edge doping region is at an edge region of the first doping region;
a first device isolator between the edge doping region and the second doping region at a first surface of the substrate;
a gate structure that is on the edge doping region and the first device isolator and includes a gate insulation layer and a gate electrode;
a first electrode that includes a first electrode portion on the first doping region and the edge doping region, and a second electrode portion electrically connected to the gate electrode; and
a second electrode that is electrically connected to the second doping region.

2. The semiconductor device of claim 1, wherein, in a plan view, the first electrode portion and the second electrode portion are spaced apart from each other, and
wherein the first electrode portion and the second electrode portion are configured to receive an equal voltage.

3. The semiconductor device of claim 1, wherein, in a plan view, the gate structure is spaced apart from the first electrode portion.

4. The semiconductor device of claim 1, wherein the gate structure further includes a first spacer at a first side of the gate structure that is adjacent the first electrode portion and a second spacer at a second side of the gate structure that is opposite to the first side of the gate structure, and
wherein, in a plan view, the first spacer is spaced apart from the first electrode portion.

5. The semiconductor device of claim 4, further comprising:
a capping layer between the first spacer and the first electrode portion,
wherein the capping layer includes a different material from the first spacer and/or the second spacer.

6. The semiconductor device of claim 5, wherein the capping layer is on the first spacer and on the gate electrode at the first side of the gate structure.

7. The semiconductor device of claim 1, wherein the first electrode and the second electrode are at a side of the first surface of the substrate.

8. The semiconductor device of claim 1, wherein the first electrode portion is in contact with the first doping region and the edge doping region.

9. The semiconductor device of claim 1, wherein the gate insulation layer is in contact with the edge doping region.

10. The semiconductor device of claim 1, wherein the first conductivity type is an n- type, and
wherein the second conductivity type is a p-type.

11. The semiconductor device of claim 1, wherein the second electrode portion is spaced apart from an inner edge of the gate electrode, and
wherein the second electrode portion is on the gate electrode.

12. The semiconductor device of claim 1, wherein the first electrode portion is in contact with the first doping region to form a Schottky junction,
wherein the first electrode portion and the second electrode portion include a same material, and
wherein the gate electrode includes a different material from the first electrode portion and the second electrode portion.

13. The semiconductor device of claim 1, wherein, in a plan view, the gate structure is spaced apart from the first doping region,
wherein a first portion of the gate structure is on the edge doping region, and
wherein a second portion of the gate structure is on the first device isolator.

14. The semiconductor device of claim 1, further comprising:
a third doping region that is spaced apart from the first device isolator and the second doping region at a side of the first surface of the substrate and has the second conductivity type;
a second device isolator that is between the third doping region and the second doping region at the side of the first surface of the substrate; and
a third electrode that is electrically connected to the third doping region,
wherein the third doping region is configured to receive a ground voltage, and
wherein the third electrode is at the side of the first surface of the substrate.

15. A semiconductor device, comprising:
a substrate that includes a n-type doping region, a field relief guard ring having a p-type conductivity, and a high concentration n-type doping region that is spaced apart from the field relief guard ring, wherein the field relief guard ring is at an edge region of the n-type doping region, and wherein the high concentration n-type doping region has a higher doping concentration than the n-type doping region at a first surface of the substrate;
a gate structure that includes a gate insulation layer and a gate electrode, wherein the gate structure overlaps the field relief guard ring in a direction that is perpendicular to the first surface of the substrate;
an anode electrode that includes a first electrode portion on the n-type doping region and the field relief guard ring to comprise a Schottky junction with the n-type doping region, and a second electrode portion that is spaced apart from the first electrode portion and is electrically connected to the gate electrode; and
a cathode electrode that is electrically connected to the high concentration n-type doping region.

16. The semiconductor device of claim 15, wherein the first electrode portion and the second electrode portion are configured to receive an equal voltage.

17. The semiconductor device of claim 15, wherein, in a plan view, the gate structure is spaced apart from the first electrode portion.

18. An electronic device, comprising:
a first semiconductor device; and
a second semiconductor device that has a different structure from the first semiconductor device, wherein the first semiconductor device includes:
a substrate that includes a first doping region having a first conductivity type, an edge doping region having a second conductivity type that is different from the first conductivity type, and a second doping region having the first conductivity type, wherein the edge doping region is at an edge region of the first doping region;
a first device isolator between the edge doping region and the second doping region at a first surface of the substrate;
a gate structure that is on the edge doping region and the first device isolator and includes a gate insulation layer and a gate electrode;
a first electrode that includes a first electrode portion on the first doping region and the edge doping region, and a second electrode portion electrically connected to the gate electrode; and
a second electrode that is electrically connected to the second doping region.

19. The electronic device of claim 18, wherein the second semiconductor device includes a transistor and/or a p-n junction diode at or on the substrate.

20. The electronic device of claim 18, wherein the electronic device is a display driver integrated circuit.
